(19) United States
(12) Patent Application Publication
(10) Pub. No.: US 2006/0245240 A1
(43) Pub. Date: Nov. 2, 2006

(54) Method and apparatus for reducing time delay through static bitlines of a static memory

(75) Inventors: Anthony Gus Aipperspach, Rochester, MN (US); Wesley H. Favors JR., Round Rock, TX (US); Peter Normand Labrecque, Austin, TX (US)

Correspondence Address: MARK P. KAHLER, 8101 VAILVIEW COVE, AUSTIN, TX, 78750, US

(73) Assignee: IBM Corporation, Austin, TX (US)

(21) Appl. No.: 11/117,144

(22) Filed: Apr. 28, 2005

(51) Int. Cl. G11C 11/00

(52) U.S. Cl. 365/154

(57) ABSTRACT

A static memory logic circuit is disclosed that may reduce bitline delay. The disclosed logic circuit partitions a bitline associated with a column of memory cells into segments. In this manner, a bitline driver in a memory cell need only drive a portion of a bitline rather than the entire bitline. This approach reduces the effective resistance and capacitance associated with the bitline, and may result in less delay through the bitline.

### TECHNICAL FIELD OF THE INVENTION

The disclosures herein relate generally to accessing data in memory and, more particularly, to the accessing data in static memory.

### BACKGROUND

Conventional memory circuits typically include an array of memory cells configured in rows and columns. Each cell can store one bit of information, namely a zero or a one. A respective word line couples to each row of the array. A respective bitline couples to each column of the array. To access the contents of a particular cell in the array, an address decoder activates the word line of the particular cell to drive the bitline of the particular cell's column. A memory controller, coupled to the memory array, can then write to or read from the cell thus addressed.

Heavily loaded bitlines may contain substantial resistance that causes significant resistor-capacitor (RC) delay and long transition times through such bitlines. One technique for decreasing the resistance and transition time of a bitline involves increasing the width of the bitline. Unfortunately, increasing the width of bitlines consumes valuable real estate in a semiconductor device. Another technique is to increase the thickness of the bitline. This approach, while decreasing the resistance of the bitline, unfortunately increases the capacitance of the bitline. Yet another approach for decreasing the transition time of a bitline involves driving a bitline with a larger driver transistor. Unfortunately, this solution also consumes valuable real estate in a semiconductor device.

What is needed is a method and apparatus that decreases the transition time of a bitline of semiconductor device.

### SUMMARY

Accordingly, in one embodiment, a method is disclosed for operating a static memory logic circuit. The method includes providing an array of memory cells situated in rows and columns. A respective read bitline is associated with each column of the array. In this array, each read bitline includes first and second read bitline segments. The method further includes driving, by a memory cell of a column, one of the first and second read bitline segments with data from the memory cell. In this manner, the entire read bitline associated with that column need not be driven by the memory cell. This method may effectively reduce the delay associated with a read bitline.

In another embodiment, a static memory logic circuit is disclosed that includes an array of memory cells arranged in rows and columns. The logic circuit further includes a plurality of read bitlines, a respective read bitline being coupled to each of the columns of memory cells. Each read bitline includes first and second read bitline segments such that a memory cell need not drive the entire read bitline with data. A plurality of bit receivers is respectively coupled to the plurality of read bitlines.

### BRIEF DESCRIPTION OF THE DRAWINGS

The appended drawings illustrate only exemplary embodiments of the invention and therefore do not limit its scope because the inventive concepts lend themselves to other equally effective embodiments.

FIG. 1 shows a simplified high level block diagram of the disclosed static memory logic circuit.

FIG. 2 shows the topology of a representative memory cell employed in static logic circuit of FIG. 1.

FIG. 3A shows a block diagram of a conventional write memory arrangement including a column of memory cells.

FIG. 3B shows a conventional read memory arrangement for the same array of memory cells depicted in FIG. 3A.

FIG. 4A shows a memory logic circuit in a write configuration.

FIG. 4B shows a memory logic circuit in a read configuration.

FIG. 4C shows write and read portions of the memory logic circuit collectively.

FIG. 4D shows an alternative embodiment of the disclosed memory logic circuit in a write configuration.

FIG. 5A shows an alternative memory logic circuit in a write configuration.

FIG. 5B shows an alternative memory logic circuit in a read configuration.

FIG. 5C shows write and read portions of the memory logic circuit of FIGS. 5A and 5B collectively.

FIG. 6 shows a general purpose information handling system (IHS) that employs the disclosed static memory logic circuit.

FIG. 7 shows a flowchart depicting representative process flow in the disclosed static memory logic circuit.

### DETAILED DESCRIPTION

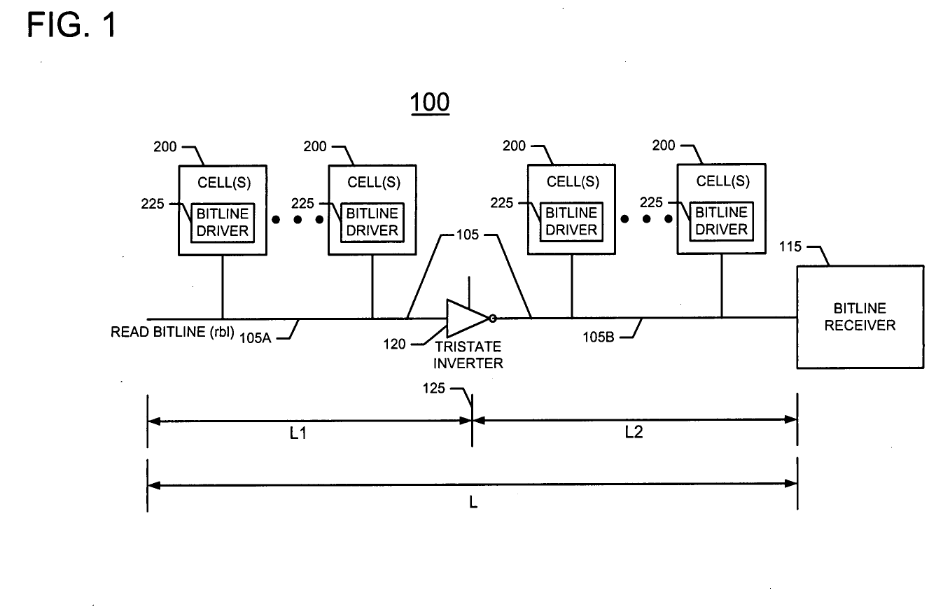

FIG. 1 shows a simplified high level block diagram of the disclosed static memory logic circuit 100. Static memory logic circuit 100 includes a read bitline (rbl) 105, of length L, that couples a bitline driver 225 of an addressed memory cell 200 to a bitline receiver 115. Bitline receiver 115 receives data from the addressed memory cell via read bitline 105. To decrease the transition time associated with read bitline 105, logic circuit 100 includes a tri-state inverter 120 situated at a partition point or cut point 125 in bitline 105. Cut point 125 partitions bitline 105 into a bitline segment 105A of length L1 and a bitline segment 105B of length L2. Memory cells 200 couple to bitline 105 along its length L as shown. When addressed, one of the cells 200 associated with bitline segment 105A drives bitline segment 105A and tristate inverter 120 while tri-state inverter 120 exhibits a low impedance state. Alternatively, when addressed, one of the cells associated with bitline segment 105B drives bitline segment 105B while tristate inverter 120 exhibits a high impedance state. Since a bitline driver 225 now drives just a portion of the entire bitline 105, namely bitline segment 105A or bitline segment 105B, the attendant resistance and capacitance encountered by bitline driver 225 decreases relative to the resistance and capacitance of the entire bitline 105.

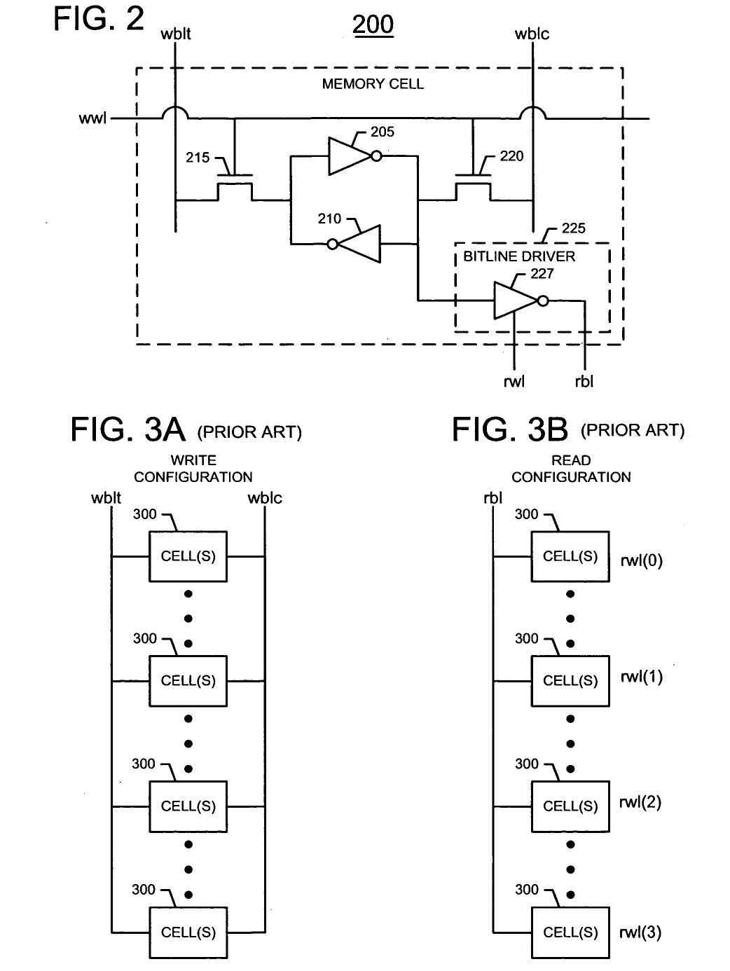

FIG. 2 shows the topology of a representative memory cell 200 employed in static memory logic circuit 100. When arranged in rows and columns as discussed later in more detail, cells 200 form a memory array useful to store digital information. Cell 200 includes cross coupled inverters 205 and 210. Transistors 215 and 220 couple to inverters 205 and 210 to provide a data bit thereto for storage. A write word line (wwl) couples to cell 200 to inform cell 200 when external circuitry (not shown) addresses a row in which cell 200 is located. A write bitline true (wblt) and a write bitline complement (wbltc) couple to transistors 215 and 220, respectively, as shown. When the write word line (wwl) goes high, cell 200's row activates. Subsequent to activation of cell 200's row, when write bitline true (wbit) goes high and write bitline complement (wblc) goes low, cell 200 becomes activated to write data therein. To provide for reading of data stored in cell 200, cell 200 includes a bitline driver 225, such as tri-state inverter 227, coupled to inverters 205 and 210 as shown. The input of tristate inverter 227 couples to the data storing inverters 205 and 210. The output of tristate inverter 227 couples to a read bitline (rbl) of cell 200. Tristate inverter 227 includes a tristate switching input that couples to a read word line (rwl) of cell 200. To read data stored in cell 200, external circuitry causes the read word line (rwl) to go high. In response, memory cell 200 outputs the stored data bit to the read bitline (rbl) when selected. In actual practice, when memory cell 200 employs an inverter 227 as bitline driver 225, inverter 227 may include multiple transistors, namely driver transistors.

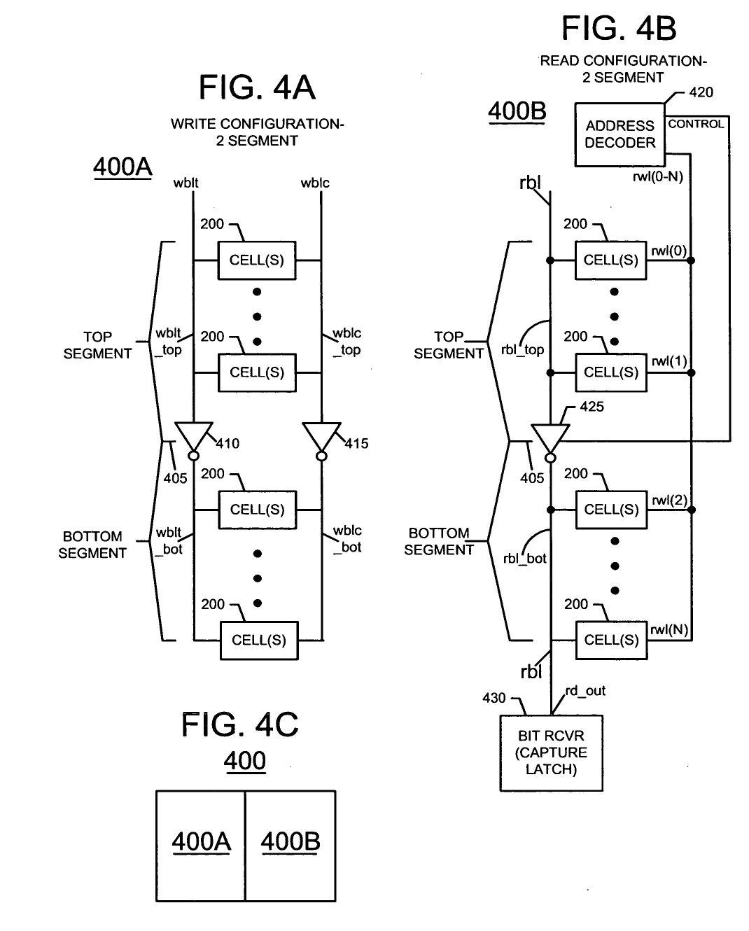

FIG. 3A shows a block diagram of a conventional write memory arrangement including a column of memory cells 300. Write bitlines, namely both write bitlines true (wblt) and write bitlines complement (wblc) couple to cells 300 as shown. Conventional memory arrangements locate several columns together to form a memory array of rows and columns.

FIG. 3B shows a conventional read memory arrangement for the same array of memory cells 300 depicted in FIG. 3A. Each of cells 300 couples to a respective read word line (rwl), namely rwl(0), rwl(1), rwl(2) and rwl(3) in this example. When external circuitry needs to read from any of cells 300, the external circuitry raises the particular word line (rwl) associated with that cell to a logic high, thus selecting the row of the cell. The particular cells in the row thus selected deposit their data on respective read bitlines (rbl). A bitline receiver (not shown) then takes this data and forwards the data to other structures as needed.

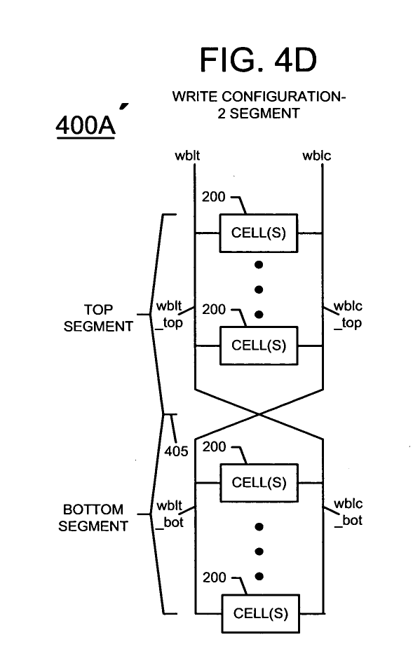

FIG. 4A and FIG. 4B show write and read portions of a memory logic circuit 400 depicted in FIG. 4C. More particularly, FIG. 4A shows a memory logic circuit 400A in a write configuration and FIG. 4B shows a memory logic circuit 400B in a read configuration. Memory logic circuit 400A includes memory cells 200 arranged in a column together with write circuitry as shown. Memory logic circuit 400B includes the same memory cells 200 arranged in a column together with read circuitry as explained below. It should be understood that FIGS. 4A and 4B repeat cells 200 for convenience of illustration. In actual practice, cells 200 of FIGS. 4A and 4B refer to the same column of cells.

FIG. 4A shows a write configuration for the column of cells 200 in memory logic circuit 400A. In actual practice, many columns such as shown in FIG. 4A combine together to form an array of rows and columns. Memory logic circuit 400A includes a write bitline true, wbit, and a write bitline complement, wblc, connected to cells 200 as shown. Write bitline, wblt, includes a partition point 405 or cut at a location along its length that partitions wbit into two segments, namely top segment wblt_top and a bottom segment, wblt_bot. Similarly, memory logic circuit 400A partitions write bitline, wblc, into two segments wblc_top and wblc_bot. Memory logic circuit 400A includes inverters 410 and 415 at partition point 405 in each of the wblt and wblc bitlines, respectively. For reasons that will become clear in the discussion of memory logic circuit 400B of FIG. 4B below, memory logic circuit 400A employs inverters 410 and 415 to invert the wblt and wblc bitlines below partition point 405 to assure correct polarity of data during read operations.

FIG. 4B shows a read configuration for the column of cells 200 in memory logic circuit 400B. Cells 200 of FIG. 4B are the same cells 200 shown in FIG. 4A, except that FIG. 4B shows read circuitry that memory logic circuit 400B employs to read data previously written in cells 200 by the write configuration depicted in FIG. 4A. Read memory logic circuit 400B includes a read bitline, rbl. Memory logic circuit 400 includes an address decoder 420 that circuit 400 employs to write data to, and read data from, addressed locations within an array of rows and columns of memory cells 200. Address decoder 420 includes a read word line output, rwl(0-N) wherein rwl(0) couples to the first row of cells 200, rwl(1) couples to the second row of cells 200, rwl(2) couples to the third row of cells 200, and rwl(N) couples to the last row of cells 200. To access a particular row of the array, address decoder 420 raises that row's read word line or rwl high. For example to read information from the uppermost cell in the column of cells 200 depicted in FIG. 4B, address decoder 420 raises the rwl(0) high to address the row in which the desired cell is located. To read information from the cell immediately below the uppermost cell of the column of cells 200 depicted in FIG. 4B, address decoder 420 raises the rwl(1) high to address the row in which the desired cell is located. In such a scenario wherein memory logic circuit 400B raises rwl(1) high to address cells in that row, this action causes the bitline driver 225 within cell 200 to drive the state of the cell onto the read bit line, rbl.

FIG. 4B also shows the partition point 405 depicted in FIG. 4A. In FIG. 4B, partition point 405 divides read bitline, rbl, into two segments, namely a top bitline segment designated rbl_top and a bottom bitline segment designated rbl_bot. A bit receiver 430 or data capture latch includes a data readout input, rd_out, coupled to the rbl_bot read bitline segment as shown to receive accessed data from read bitline rbl. A tristate inverter 425 couples top segment rbl_top to bottom segment rbl_bot at partition point 405 as shown. Address decoder 420 includes a control output coupled to the tristate switch input of tristate inverter 425. In this manner, address decoder 420 may transmit a control signal to tristate inverter 425 to instruct tristate inverter when to conduct signals therethrough and, alternatively, when to exhibit a high impedance state. Tristate inverter 425 acts as a controllable active coupling element that operates under the direction of the control signal from address decoder 420.

In memory logic circuit 400B the bitline driver of a selected memory cell 200 need only drive a portion of read bitline rbl at a time. For example, if address decoder 420 needs to address cell 200 in the second row, namely a cell associated with the top segment rbl_top, then address decoder 420 transitions the read word line rwl(1) high to select that cell 200. Address decoder 420 also transitions the control signal fed to the control input of tristate inverter 425 high to cause tristate inverter 425 to enter a conductive state. The tristate inverter 425 in read bit line rbl thus provides a conductive path for data read from a cell 200 at rbl_top to bit receiver 430 located at the end of the read bitline rbl. In this scenario, the bitline driver of the addressed memory cell 200 associated with top segment rbl_top need only drive a portion of read bitline rbl, namely top segment rbl_top. Tristate inverter 425 drives the data from top segment rbl_top to bit receiver 430.

However, if address decoder 420 needs to address a cell 200 in the third row, namely a cell associated with bottom segment rbl_bot, then address decoder 420 transitions the read word line rwl(2) high to select that cell 200. Address decoder 420 also transitions the control signal fed to the control input of tristate inverter 425 low to cause tristate inverter 425 to enter a nonconductive or high impedance state. This action effectively decouples bottom segment rbl_bot from top segment rbl_top. Thus, in this scenario, the bitline driver of the addressed memory cell 200 associated with bottom segment rbl_bot need only drive a portion of readbit line rbl, namely bottom segment rbl_bot. The bitline driver in the addressed memory cell drives the data from that cell to bottom segment rbl_bot where the data travels to bit receiver 430.

Tri-state inverter 425 inverts the polarity of data read from cells 200 associated with the rwl(0) and rwl(1) read word lines. To assure that memory logic circuit 400B reads the correct polarity data from cells 200 associated with the bottom segment, namely the same polarity as data in cells 200 associated with the top segment, memory logic circuit 400A of FIG. 4A includes inverters 410 and 415 to pre-invert the data stored in bottom segment cells. The combination of pre-inversion by inverters 410 and 415 together with the inversion associated with tristate inverter 425 effectively returns data polarity associated with the bottom segment of circuit 400B to the same polarity as data associated with the top segment of circuit 400B. In an alternative embodiment, write memory logic circuit 400′ of FIG. 4D attains a similar pre-inversion effect by “criss-crossing” or twisting the write bitlines wbit and wblc at transition point 405 as shown. In this manner, write memory logic circuit 400′ inverts data written into cells 200 associated with write bitline bottom segment wblt_bot of circuit 400A′ in FIG. 4D.

While FIGS. 4A and 4B show a memory logic circuit with bitlines cut into two segments, the bitlines may be cut into other numbers of segments as desired for a particular application. For example the bitlines may be segmented into 3 or more segments. Moreover, the segments need not necessarily each contain the same number of cells or exhibit the same length. One segment may contain fewer or more cells than another segment depending up the particular application. One segment may be longer than the other segment.

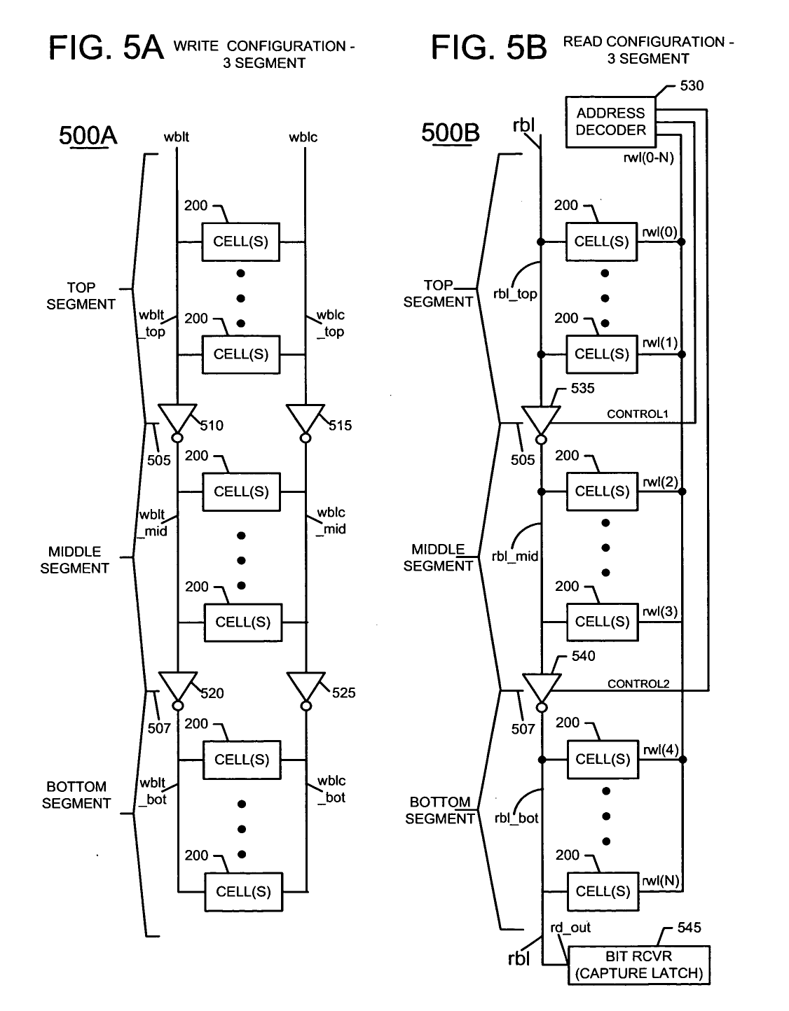

FIG. 5A shows a write memory logic circuit 500A configured for writing data to cells 200. In this embodiment, the write bitlines wblt wblc include 3 segments. FIG. 5B shows a read memory logic circuit 500B configured for reading data previously written to cells 200 by memory logic circuit 500A of FIG. 5A. The read bitlines rbl of read memory logic circuit 500B include 3 segments. Together, write memory circuit 500A and read memory circuit 500B form a memory logic circuit 500 that includes both write and read capabilities. FIG. 5C shows memory logic circuit 500. While for illustrative convenience FIG. 5A shows a column of cells 200 and FIG. 5B show another column of cells 200, these drawings in fact illustrate the same column of cells. In actual practice, memory logic circuit 500 includes several columns of cells 200 to form an array of cells 200 including rows and columns.

In more detail as seen in FIG. 5A, write memory logic circuit 500A includes write bitlines wblt and wblc, wherein wblt designates write bitline true and wblc designates write bitline complement. Write memory logic circuit 500A of FIG. 5A exhibits similarity to write memory logic circuit 400A of FIG. 4A. In the embodiment illustrated, the upper two segments and associated circuitry of write memory logic circuit 500A of FIG. 5A exhibit substantial similarity to the two segments and associated circuitry of write memory logic circuit 400A of FIG. 4A. Write memory logic circuit 500A segments the write bitline wblt into 3 segments, namely a top segment wbit_top, a middle segment wbit_mid, and a bottom segment wbit_bot as shown. More particularly, write memory logic circuit 500A includes a partition point 505 that segments write bitline wblt into segments wblt_top and wblt_mid. In a similar manner, write memory logic circuit 500A includes a partition point 507 that segments write bitline wblt into segments wblt_mid and wblt-bot as shown. Write memory logic circuit 500A includes inverters 510 and 515 situated at partition point 505 in write bitlines wbit and wblc, as shown. Inverters 510 and 515 perform substantially the same data polarity correcting function that inverters 410 and 415 perform in memory logic circuit 400 described above. Write memory logic circuit 500A also includes inverters 520 and 525 situated at partition point 507 in write bitlines wblt and wblc, as shown. Inverters 520 and 525 perform a data polarity correcting function.

As seen in FIG. 5B, write memory logic circuit 500B includes a read bitline rbl that couples to a column of cells 200. In a manner similar to the write bitlines of write memory logic circuit 500A of FIG. 5A, read bitline rbl includes partition points 505 and 507 that partition or segment read bitline rbl into a top segment rbl_top, a middle segment rbl_mid and a bottom segment rbl_bot as shown in FIG. 5B. The two rows of cells 200 associated with top segment rbl_top include read word lines rwl(0) and rwl(1), respectively. The two rows of cells 200 associated with middle segment rbl_mid include read word lines rwl(2) and rwl(3), respectively. Finally, the two rows of cells 200 associated with bottom segment rbl_bot include read word lines rwl(4) and rwl(N), respectively, wherein N designates the total number of cells in the memory array formed by arranging cells 200 in rows and columns.

Read memory logic circuit 500B includes an address decoder 530 with an read word line output rwl(0-N) that couples to read word lines rwl(0), rwl(1), . . . rwl(N). In this manner address decoder 530 can access a particular cell in a column of a memory array by activating the read word line associated with the row that includes the particular cell. Read memory logic circuit 500B includes tristate inverters 535 and 540 at partition points 505 and 507, respectively, of the read bitline rbl so that the entire read bitline rbl need not be driven to access data. To access data in cells 200 associated with top segment rbl_top, address decoder 530 signals tristate inverters 535 and 540 via control lines CONTROL1 and CONTROL2, respectively, to enter the conductive state. In this manner, data from top segment rbl_top flows via inverters 535 and 540 to bit receiver 545. To access data in cells 200 associated with middle segment rbl_mid, address decoder 530 signals tristate inverter 535 via the CONTROL1 line to transition to a high impedance state. This action effectively decouples middle segment rbl_mid from top segment rbl_top. Address decoder also signals tristate inverter 540 to enter the conductive or low impedance state. In this manner, data from middle segment, rbl_mid flows via inverter 540 to bit receiver 545. Again, the entire read bitline rbl need not be driven to access data in cells associated with middle segment rbl_mid. Similarly, to access data in cells 200 associated with bottom segment rbl_bot, address decoder 530 signals tristate inverter 540 via the CONTROL2 line to transition to a high impedance state. This action effectively decouples bottom segment rbl_bot from middle segment rbl_mid. In this manner, data from a cell associated with bottom segment, rbl_bot, flows to bit receiver 545 without the bitline driver of that cell being loaded down by top segment rbl_top and middle segment nbl_mid.

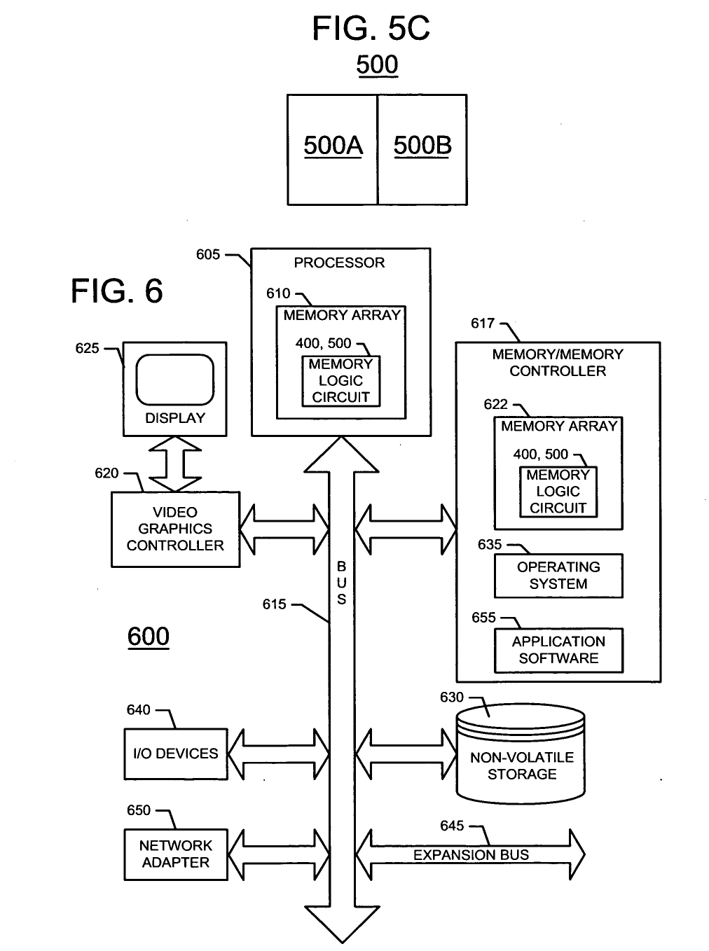

FIG. 6 shows a general purpose information handling system (IHS) 600 including a processor 605 with a memory array 610 of cells configured as memory logic circuit 400 or 500 in this particular example. Bus 615 couples processor 605 to a memory/memory controller 617 and video graphics controller 620. Memory/memory controller 617 may employ conventional system memory or a memory array 622 of cells configured as memory logic circuit 400 or 500. A display 625 couples to video graphics controller 620. Nonvolatile storage 630, such as a hard disk drive, CD drive, DVD drive, or other nonvolatile storage couples to bus 615 to provide IHS 200 with permanent storage of information. An operating system 635 loads in memory 617 to govern the operation of IHS 600. In actual practice, operating system 635 loads in memory array 622. I/O devices 640, such as a keyboard and a mouse pointing device, couple to bus 615. One or more expansion busses 645, such as USB, IEEE 1394 bus, ATA, SATA, PCI, PCIE and other busses, couple to bus 617 to facilitate the connection of peripherals and devices to IHS 600. A network adapter 650 couples to bus 615 to enable IHS 600 to connect by wire or wirelessly to other IHSs or devices. IHS 600 loads application software 655 from nonvolatile storage 630 to memory array 622 for execution. The particular application software 655 loaded into memory 617 of IHS 600 determines the operational characteristics of IHS 600. While FIG. 6 shows an IHS that employs the disclosed memory logic circuit, the IHS may take many forms. For example, IHS 600 may take the form of a desktop, server, portable, laptop, notebook, or other form factor computer system. IHS 600 may take other from factors such as a personal digital assistant (PDA), a gaming device, a portable telephone device or other media devices that include a processor and memory

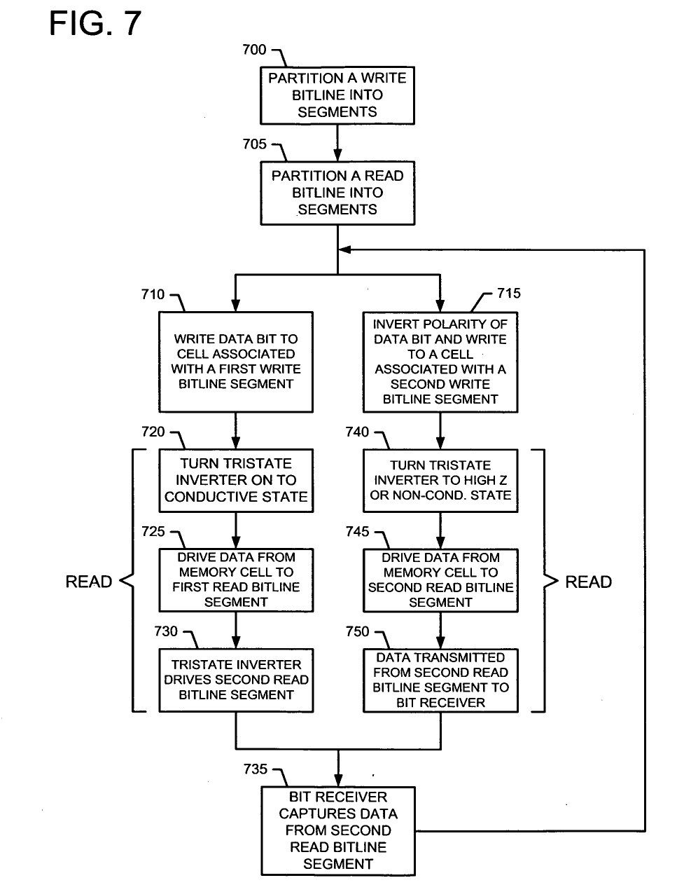

FIG. 7 shows a flowchart that describes process flow in the disclosed static memory logic circuit. The disclosed process or method includes partitioning a write bitline and a read bitline associated with a column of memory cells into segments as per blocks 700 and 705, respectively. The memory logic circuit then writes a data bit to a cell associated with a first write bitline segment, for example the top segment, as per block 710. Alternatively, to write to a memory cell associated with the second write bitline segment, for example the bottom segment, the memory logic circuit inverts the polarity of the data bit before writing that data bit to the second write bitline segment as per block 715. The memory logic circuit achieves writing of data to memory cells in this manner.

To read a memory cell associated with a first read bitline segment, for example the top read bitline segment, the memory logic circuit turns tristate inverter 425 on to a conductive state as per block 720. The bitline driver in the addressed memory cell then drives its data onto the first read bitline segment as per block 725 Tristate inverter 425 then drives that data onto the second read bitline segment as per block 730. Bit receiver 430 captures the data presented by the second read bitline segment as per block 735.

Alternatively, to read a memory cell associated with a second read bitline segment, for example the bottom read bitline segment, the memory logic circuit turns tristate inverter 425 to a high impedance or nonconductive state as per block 740. The bitline driver in the addressed memory cell then drives its data onto the second read bitline segment as per block 745. The second read bitline segment then transmits the data to bit receiver 430, as per block 750. Bit receiver 430 captures the data presented by the second bitline segment, as per block 735. Process flow then continues back to block 710 and 715 at which data are again written to memory cells, and the process repeats as needed.

The foregoing discloses a method and apparatus that may reduce delay through the bitlines of a static memory logic circuit. The methodology cuts the bitline into segments such that the memory logic circuit need not drive the entire bitline to access data.

Modifications and alternative embodiments of this invention will be apparent to those skilled in the art in view of this description of the invention. Accordingly, this description teaches those skilled in the art the manner of carrying out the invention and is intended to be construed as illustrative only. The forms of the invention shown and described constitute the present embodiments. Persons skilled in the art may make various changes in the shape, size and arrangement of parts. For example, persons skilled in the art may substitute equivalent elements for the elements illustrated and described here. Moreover, persons skilled in the art after having the benefit of this description of the invention may use certain features of the invention independently of the use of other features, without departing from the scope of the invention.

What is claimed is:

1. A method of operating a static memory logic circuit, the method comprising:
providing an array of memory cells situated in rows and columns, a bitline being associated with a column of the array, the bitline including first and second bitline segments; and
driving, by a memory cell of the column, one of the first and second bitline segments with data from the memory cell such that the entire bitline associated with that column need not be driven by the memory cell.

2. The method of claim 1, wherein the bitline comprises a read bitline.

3. The method of claim 1, further comprising coupling the first bitline segment to the second bitline segment, by a coupling element exhibiting a low impedance state, when a memory cell drives data onto the first bitline segment.

4. The method of claim 3, wherein the data driven onto the first bitline segment flows through the coupling element and the second bitline segment to a bit receiver coupled to the second bitline segment.

5. The method of claim 3, wherein the coupling element switches to a high impedance state to decouple the first bitline segment from the second bitline segment, when a memory cell drives data onto the second bitline segment.

6. The method of claim 5, wherein the second bitline segment supplies the data to a bit receiver coupled to the second bitline segment.

7. The method of claim 3, wherein the coupling element is a tristate inverter coupled between the first and second bitline segments.

8. A static memory logic circuit comprising:
an array of memory cells arranged in rows and columns;
a plurality of read bitlines, a respective read bitline being coupled to each of the columns of memory cells, each read bitline including first and second read bitline segments such that a memory cell need not drive the entire read bitline with data; and
a plurality of bit receivers coupled to the plurality of read bitlines, respectively.

9. The static memory logic circuit of claim 8, wherein each read bitline includes a coupling element between the first and second read bitline segments.

10. The static memory logic circuit of claim 9, wherein the coupling element is a tristate inverter.

11. The static memory logic circuit of claim 9, further comprising an address decoder, coupled to the memory cells of a column, that instructs the coupling element to exhibit a low impedance state when the address decoder addresses a memory cell associated with the first read bitline segment, so that data driven onto the first read bitline segment by a memory cell flows through the first read bitline segment via the coupling element to the second read bitline segment to a bit receiver.

12. The static memory logic circuit of claim 9, wherein the address decoder instructs the coupling element to exhibit a high impedance state when the address decoder addresses a memory cell associated with the second read bitline segment, so that data driven onto the second read bitline segment by a memory cell flows through the second read bitline segment to a bit receiver coupled to the second read bitline segment.

13. The static memory logic circuit of claim 8, wherein each memory cell includes a driver transistor.

14. The static memory logic circuit of claim 8, wherein the plurality of read bitlines includes a third read bitline segment.

15. The static memory logic circuit of claim 8, further comprising:
a plurality of read word lines coupled to respective rows of memory cells; and
a plurality of write word lines coupled to respective rows of the memory cells.

16. The static memory logic circuit of claim 8, further comprising a plurality of write bitlines coupled to the respective columns of the memory cells.

17. The static memory logic circuit of claim 16, wherein the write bitlines each include first and second write bitline segments with a partition point therebetween, data transmitted from the first write bitline segment to the second write bitline segment during a write operation being inverted at the partition point.

18. An information handling system (IHS) comprising:
a processor including a static memory logic circuit, the static memory logic circuit including:
an first array of memory cells arranged in rows and columns; and
a plurality of first read bitlines coupled to respective columns of the first array, each first read bitline being partitioned into a plurality of segments such that the entire first read bitline need not be driven to access data in a memory cell; and
a system memory coupled to the processor.

19. The IHS of claim 19, wherein the system memory includes:
an second array of memory cells arranged in rows and columns; and
a plurality of second read bitlines coupled to respective columns of the second array, each second read bitline being partitioned into a plurality of segments such that the entire second read bitline need not be driven to access data in a memory cell.

20. The IHS of claim 18, wherein the IHS is a computer system.
